(19) United States
(12) Patent Application Publication
(10) Pub. No.: US 2004/0070426 A1
(43) Pub. Date: Apr. 15, 2004

(54) Oligonucleotide - based logic gates and molecular networks

(76) Inventor: Milan N. Stojanovic, Fort Lee, NJ (US)

Correspondence Address: John P. White, Cooper & Dunham LLP, 1185 Avenue of the Americas, New York, NY, 10036, US

(21) Appl. No.: 10/371,550

(22) Filed: Feb. 21, 2003

Related U.S. Application Data
(60) Provisional application No. 60/359,195, filed on Feb. 21, 2002.

(51) Int. Cl. H03K 19/00

(52) U.S. Cl. 326/136

(57) ABSTRACT

A set of deoxyribozyme-based logic gates are capable of generating any Boolean function. The gates include basic NOT and AND gates, and the more complex XOR gate. These gates were constructed through modular design that combines molecular beacon stem-loops with hammerhead-type deoxyribozymes. The gates have oligonucleotides as both inputs and output, thereby communication between various computation elements in solution. The operation of these gates is conveniently connected to a fluorescent readout.

### REFERENCE TO GOVERNMENT RIGHTS

Some of the work reported herein was support by the Counterdrug Technology Center of the Office of National Drug Control Policy and an National Institutes of Health postodoctoral fellowship. The United States may have certain rights herein.

### BACKGROUND OF THE INVENTION

The present invention relates to oligonucleotide logic gates and networks and more particularly to nucleric acid-based logic gates and their combination in networks.

Throughout this application, various publications are referenced to as footnotes or within parentheses. Disclosures of these publications in their entireties are hereby incorporated by reference into this application to more fully describe the state of the art to which this invention pertains. Full bibliographic citations for these references may be found at the end of this application, preceding the claims.

There is an interest in the development of molecular scale computational elements(1) as crucial components of multifunctional molecular platforms that can convert specific recognition of multiple molecular disease markers to intervention at the cellular level. One goal in this field is to construct macromolecular systems able to enter specific cell types and therein sense multiple molecular markers of diseases. Ensuing signals could be analyzed to result in a simple binary output, e.g., cell-death or cell-survival.

Oligonucleotides(2, 3) have been identified as candidates for platform components for the following reasons: (i) various selection and amplification procedures can rapidly generate specific sensitive oligonucleotide-based recognition elements (“aptamers”) against protein disease signatures(4,5); (ii) short aptamers can be selected to recognize and, consequently, home-in on cellular surface markers(6); (iii) significant knowledge regarding the stability and intracellular delivery of oligonucleotides has been acquired in development of antisense therapeutics⁷ and gene delivery; (iv) recognition elements based on oligonucleotides(8) or small-molecules(⁹) can be modularly attached to the catalytic nucleic acids to yield aptazymes or allozymes that act as sensors using product oligonucleotides (modified through cleavage or ligation) as outputs and small molecules(⁸)or proteins(^{9,10}) as inputs; and (v) changes in secondary structures of aptamers can be coupled to recognition(¹¹) of analytes by oligonucleotides with a concurrent potential for triggering drug delivery(¹²).

In order to construct an integrated macromolecular platform, its elements should be able to communicate to each other without macroscopic interfaces. It has been recognized that the primary obstacle to development of practical applications of molecular scale computation is the inability to establish communication among the inputs and output of individual elements in solution^{1a, 13}

### SUMMARY OF THE INVENTION

The present invention provides an oligonucleotide logic gate. General allosteric control of deoxyribozymes (DNA-based catalysts¹⁴), with phosphodiesterase activity by oligonucleotides is important in this context¹⁵, because the product oligonucleotide (output) of one catalyst could be used as an allosteric effector (input) of another catalyst, thereby allowing communication between various elements of the multifunctional platform without a change in phase.

The present invention also provides deoxyribozymes that behave as molecular-scale logic gates,(^{1a}) thus taking the key step toward developing the analytical function of the oligonucleotide-based multifunctional molecular platforms.

According to one aspect of the invention, a logic gate is provided comprising at least one input, at least one output, at least one oligonucleotide with catalytic activity and at least one stem-loop which controls the catalytic activity of the gate, wherein each said output is capable of at least two different output states, said states depending on the catalytic activity of the gate.

According to another aspect of the invention, the logic gate may be arranged and used to detect a disease marker, wherein the disease marker has been translated into an oligonucleotide. The logic gate may be arranged and used to signal a disease marker, wherein the disease marker has been translated into an oligonucleotide.

According to another aspect of the invention, a plurality of logic gates of the type described above is provided, wherein the output of one gate is arranged as the input of another gate. The product of one gate may be arranged to be the input of another gate.

According to another aspect of the invention, a logic gate performing a catalytic function as a logic operation is provided, said gate having at least one input and at least one output, said gate providing an output having a characteristic which depends on a characteristic of the input, said output characteristic being sufficient to be provided as an input characteristic to a second logic gate.

According to another aspect of the invention, a method of performing a logical operation is provided using a logic gate having catalytic activity, at least one input, and an output capable of at least two different output states, said states depending on the catalytic activity of the gate, said logic gate further comprising at least one oligonucleotide and at least one stem-loop which controls the gate catalytic activity, which method comprises the steps of:

1) binding at least one input to a complementary loop within a stem-loop, to thereby open the corresponding stem, and

2) cleaving a substrate, wherein cleavage of the substrate indicates that a logical operation has been performed.

According to another aspect of the invention, a method of performing a logical operation is provided using a logic gate having catalytic activity, at least one input, and an output capable of at least two different output states, said states depending on the catalytic activity of the gate, said logic gate further comprising at least one oligonucleotide and at least one stem-loop which controls the gate catalytic activity, which method comprises the steps of:

1) binding at least one input to a complementary loop within a stem-loop, to thereby open the corresponding stem, and

2) inhibiting cleaving of a substrate, wherein inhibition of the cleavage of the substrate indicates that a logical operation has been performed.

### DESCRIPTION OF THE DRAWINGS

FIG. 1: Basic concept: input oligonucleotides IA and IB result in the presence or absence of output fluorescent product OF depending on the interactions with deoxyribozyme-based logic gates.

FIG. 2: Fluorogenic cleavage of double end-labeled substrate by deoxyribozymes 12E or 8-17 into products OF and OR. Fluorescein (F) emission is quenched by distance dependent fluorescence resonance energy transfer to tetramethylrhodamine (R), and upon cleavage fluorescence increases (larger font F).

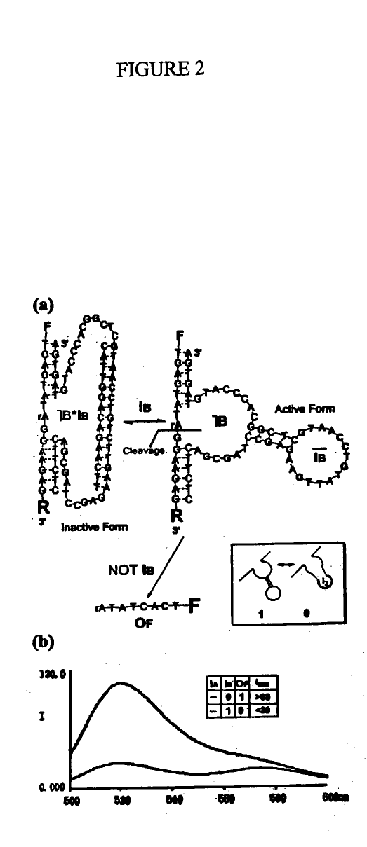

FIG. 2A: Deoxyribozyme Logic: Basic Technologies.

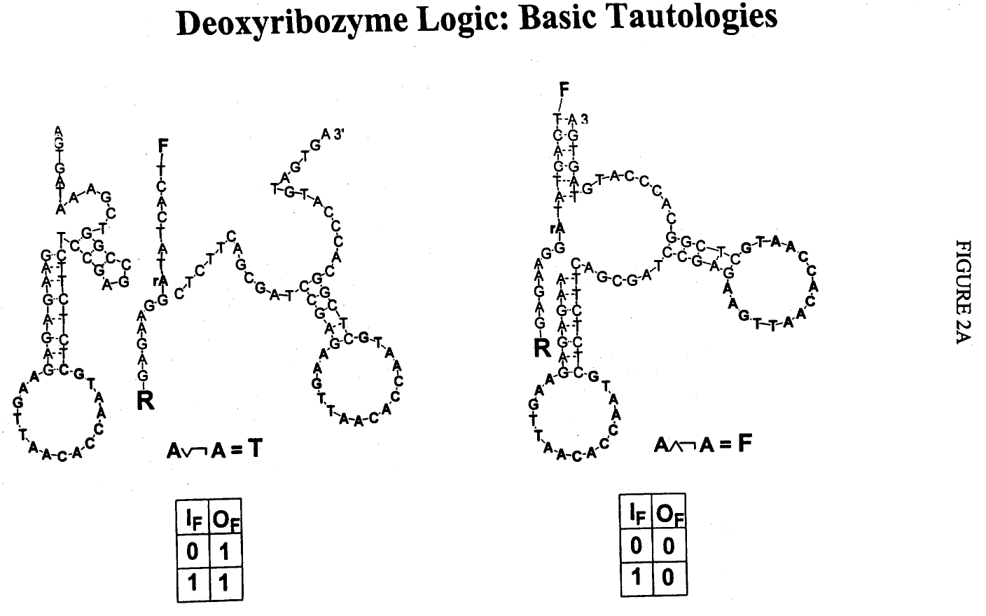

FIG. 3: Single input sensor gate (A) is activated by the input oligonucleotide 1A. For design principles, please see ref. 15a. Other input oligonucleotide 1B does not activate deoxyribozyme. Insert in box schematically represents inactive gate with closed loop (output 0) and active gate with open loop (output 1); Graph shows fluorescene spectra (relative intensity vs. emission wavelength, (λ_{EXC}=480 nm, t=6 h) of the solution containing gate, S, and either (from top to bottom) IA (Output 1, upper curve) or no input oligonucleotide (lower); insert: truth table for YES gate.

FIG. 4: Single-input NOT gate ( [symbol] B) is constructed through substitution of a non-conserved loop in the deoxyribozyme with beacon stem loop complementary to the input. Deoxyribozyme is inactive in the complex with I_{B}, while 1_{A} has only minimal inhibitory influence; insert in box schematically represents active gate with closed loop (output 1) and inactive gate with open loop (output 0); Graph shows fluorescence spectra (relative intensity vs. emission wavelength, (λ_{EXC}=480 nm, t=12 h) of the solution containing gate, S, and either (from top to bottom): no input oligonucleotides (output 1, upper curve) or 1B (output 0, lower curve); insert: truth table for NOT gate.

FIG. 4A: Deoxyribozyme—Based Sensors for Proteins: NOT Streptavidine Gate.

FIG. 4B: OR Gate and NANO Gate.

FIG. 4C: Connection through product.

FIG. 5: AND gate (A\hat{ }B) is constructed through attachment of two loops complementary to input oligonucleotides to the 5′ and 3′ ends of the deoxyribozyme; deoxyribozyme is active only if both inputs are present; insert in box schematically presents inactive gate (output 0) with either one or both loops closed, and active gate with both loops open (output 1); Graph shows fluorescence spectra (relative intensity vs. emission wavelength, (λ_{EXC}=480 nm, t=12 h) of the solution containing A\hat{ }B, S, and (from top to bottom): I_{A} and I_{B} (output 1, top curve), only I_{B}, only I_{A} and no input oligonucleotides (bottom three curves); insert: truth table for AND gate.

FIG. 6: (a) A sensor-inhibitor AND NOT gate (A\hat{ } [symbol] B) is constructed through attachment of two loops complementary to input oligonucleotides, one at the 5′ end, one at the non-conserved loop; catalytic activity in solution is present only if I_{A} is present and I_{B} is absent; insert in box schematically represents three inactive states of the gate (outputs 0) with 5′ loop closed (first) or internal loop open (third) or both (fourth) and one active state of the gate (output 1, second) with 5′ loop open and internal loop closed; Graph shows fluorescence spectra (relative intensity vs. emission wavelength, (λ_{EXC}=480 nm, t=12 h) of the solution containing this gate, S, and; only I_{A} (output 1, top curve), I_{A} and I_{B}, only I_{B} and no input oligonucleotides (bottom three curves); insert; truth table for AND NOT gate.

FIG. 7: XOR gate (AvB) as a combination of A\hat{ } [symbol] B and B\hat{ } [symbol] A with same inputs and output; catalytic activity is present in solution if either I_{A} or I_{B} is present, but not both; insert in box schematically represents the two active states (output 1) of the XOR system, when only one oligonucleotide is present (second or third), and two inactive states (output 0) with either neither (first) or both (fourth) oligonucleotides present; Graph shows fluorescence spectra (relative intensity vs. emission wavelength, ^{λ}ₑₘ=520 nm, λ_{EXC}=480 nm, t=12 h) of the solution containing AvB, S and (from top to bottom): only I_{A} (top curve), only I_{B} (second curve), both (third curve), and no input oligonucleotides (fourth curve); insert: truth table for XOR gate.

FIG. 8: Deoxyribozyme-based half-adder, demonstrating parallel operation of two logic gates; XOR gate will be active and yield product if only one of the inputs is present, not both; AND gate will be active only if both inputs are present. Substrates are engineered to allow for multicolor detection. (BH—black hole quenchers; F—fluorescein, R—rhodamine). Inserts represent corresponding truth table.

FIG. 9: Operation of NOT streptavidine sensor gate and YES oligonucleotide gate in series; Product of NOT streptavidine gate activates YES oligonucleotide gate, while the substrate does not. A downstream YES gate is active only if the upstream streptavidine gate is active, i.e. if streptavidine is absent (I_{S}=0). Note the translation of output into O_{F}.

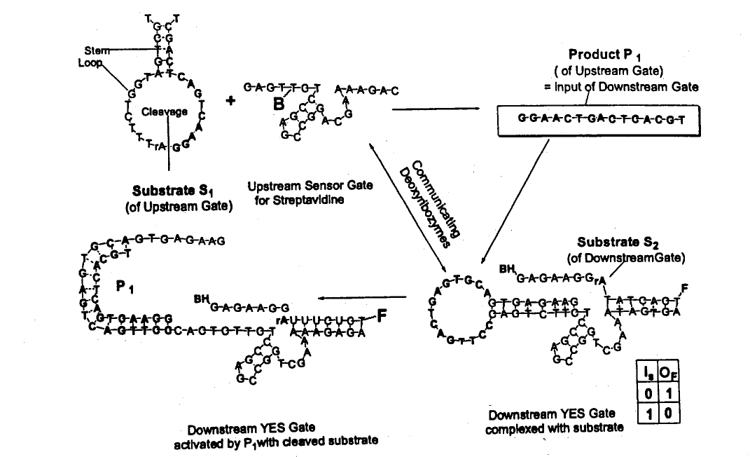

FIG. 10: Operation of NOT streptavidine sensor gate and NOT oligonucleotide sensor gate in series (truth table with O_{F} as an output). Substrate of upstream NOT streptavidine gate inhibits NOT oligonucleotide gate, while products do not. Note the translation of the output.

FIG. 11: Construction of a system that behaves and NAND gate from: 1. Clocking Module, which synchronizes activity of NOT oligonucleotide-sensor gate with AND Gate; 2. AND gate, that cleaves substrate constrained into stem-loop structure, and yields product which inhibits NOT oligonucleotide gate; 3. NOT oligonucleotide sensor gate, which is inhibited by two oligonucleotides, one is the substrate of clocking deoxyribozyme, and the other product of AND gate. Note that NOT module is inactive only if AND module is active, i.e. when both input oligonucleotides are present in the solution. Insert in NOT module describes truth table of a NOT gate in this network, behaving as a NAND gate in regard to input E, S and I denote enzymes, substrates and inputs of corresponding modules.

FIG. 12: Basic principle of deoxyribozyme chain reaction; Input oligonucleotide activates sensor gate, which cleaves substrate into another input oligonucleotide and an output oligonucleotide for downstream gate. Thus, each input oligonucleotide starts a chain reaction, as sensor gates have multiple turnovers.

FIG. 13: The network of deoxyribozymes active only in the presence of one input, small molecule (represented as YES cocaine gate), or protein (NOT streptavidine gate) or oligonucleotide (YES oligonucleotide gate). Three sensor inputs (YES cocaine with reversal of inhibition by an anti-cocaine antibody, NOT streptavidine and YES oligonucleotide) are connected through their oligonucleotide outputs to three separate analytical modules, each active if only one of the inputs is present, and the other two absent. The analytical modules operate in the implicit OR fashion, as they share the same substrate. Arrows represent downstream connectivity. The streptavidine only module is different as the sensor gate for the streptavidine is a NOT gate. The triple input in this module is a combination of YES and AND NOT gates.

FIG. 14: A network of three AND gates, with outputs of two AND gates connected as inputs to a third AND gate.

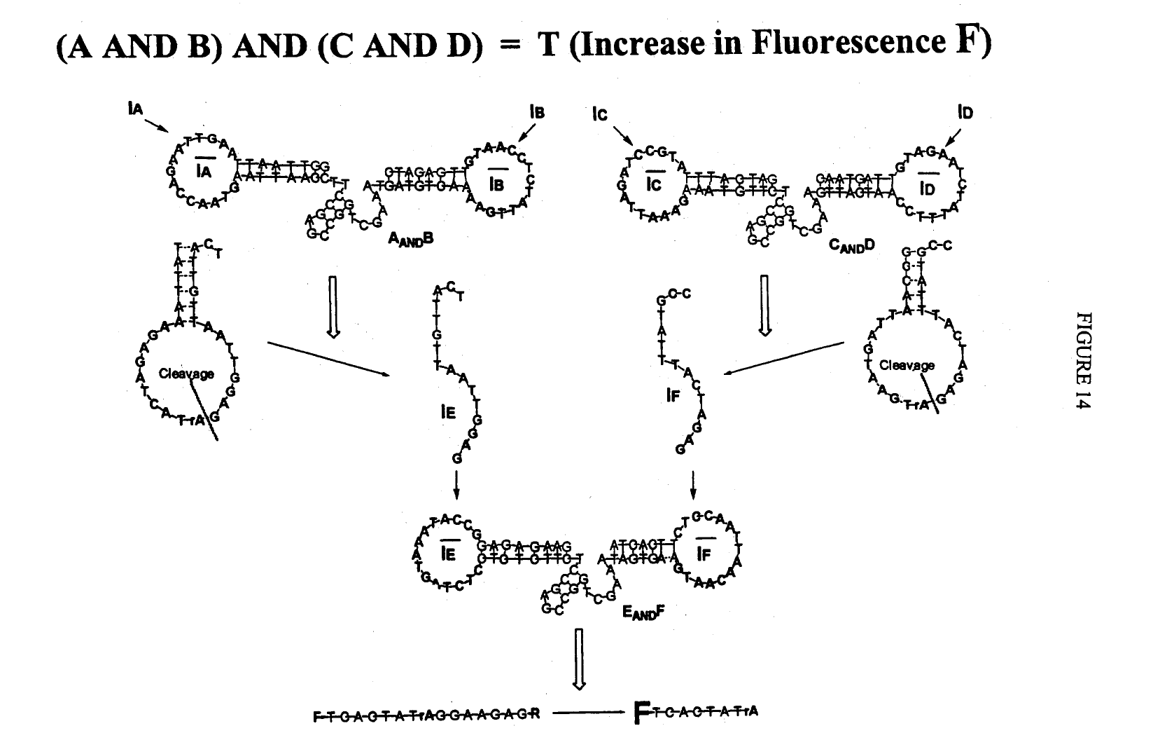

FIG. 15: A network of gates, including an OR gate and AND gate, whose outputs are connected as inputs to another AND gate.

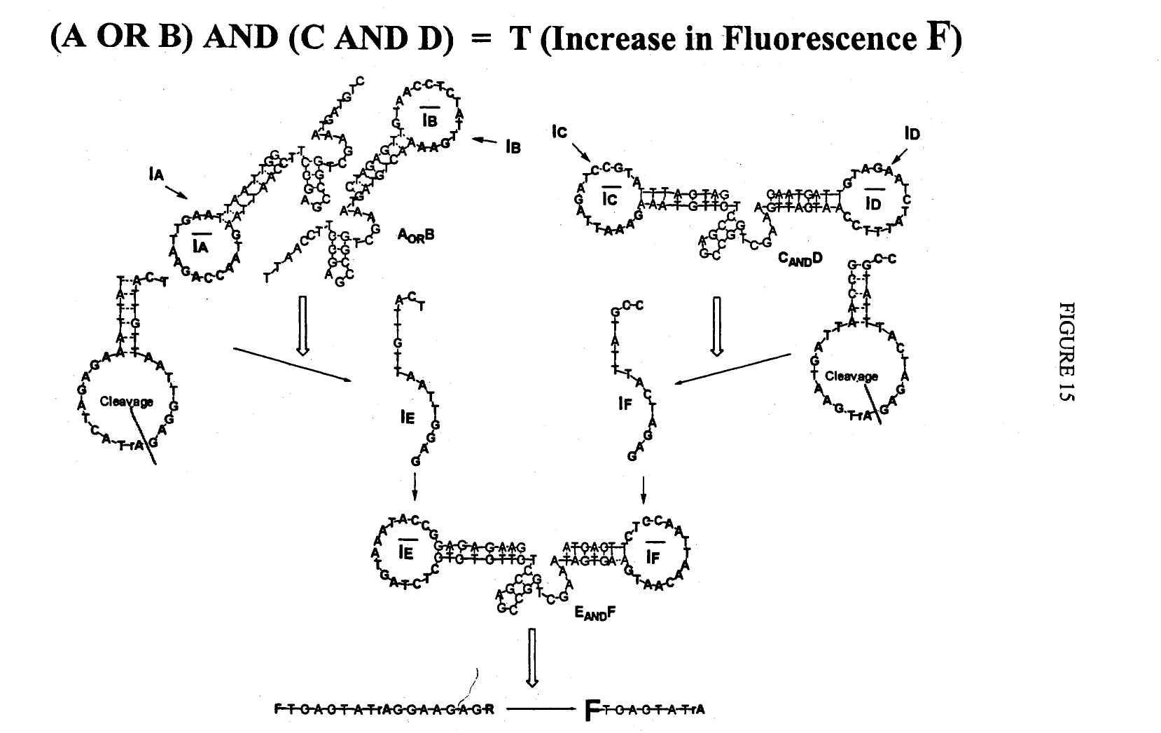

FIG. 16: Catalytic Deoxyribozyme-based Nanoassemblies.

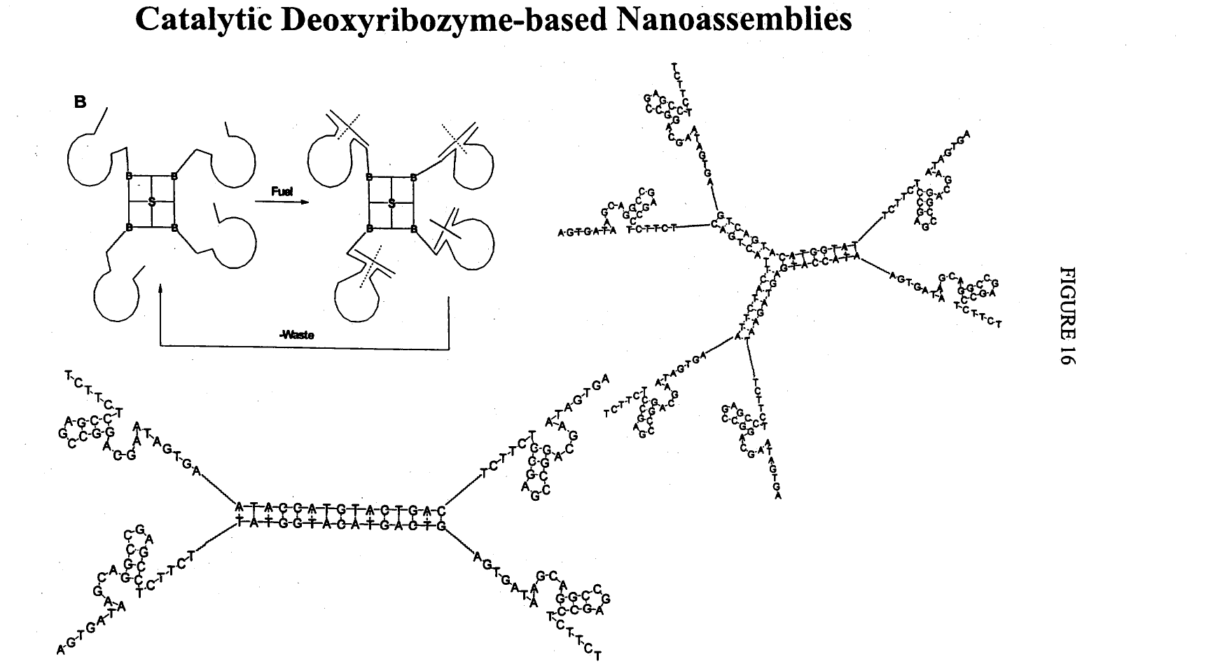

FIG. 17: Decision-making Multi-layered Molecular Networks.

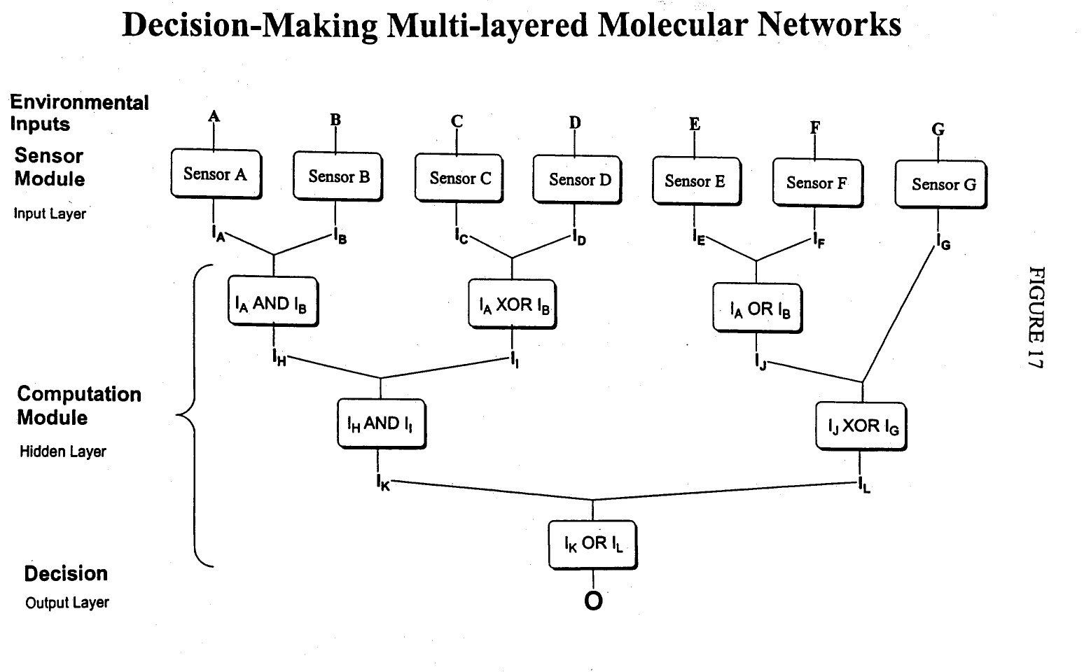

### DETAILED DESCRIPTION OF THE PREFERRED EMBODIMENTS

According to one aspect of the invention, a logic gate is provided comprising at least one input, at least one output, at least one oligonucleotide with catalytic activity and at least one stem-loop which controls the catalytic activity of the gate, wherein each said output is capable of at least two different output states, said states depending on the catalytic activity of the gate.

The configuration of the stem-loop preferably determines the output state. The gate preferably has one input, and a first output state when the stem-loop is closed and a second output state when the stem-loop is open. The first output state may correspond to a logical off and the second output state may correspond to a logical on. Alternatively, the first output state may correspond to a logical on and the second output state may correspond to a logical off.

The output of the gate may comprise a fluorescent readout, electromagnetic readout, colorimetric readout, radiation readout, a light emission readout, and/or an ultraviolet spectral change readout.

The output of the gate may comprise a material whose conductivity changes to indicate the output states. The output of the gate may comprise a material whose magnetization changes to indicate the output state.

The stem-loop may comprise an oligonucleotide. The oligonucleotide may comprise a peptide nucleic acid. The logic gate may comprise peptide nucleic acid. The stem-loop may comprise peptide nucleic acid. The logic gate may comprise DNA. The logic gate may comprise RNA. The DNA may comprise natural DNA. The DNA may comprise synthetic DNA. The RNA may comprise natural RNA. The RNA may comprise synthetic RNA. The logic gate may comprise both natural and synthetic nucleotides.

At least one input may comprise an oligonucleotide. The logic gate may further comprise at least one input based on hybridization. The logic gate may further comprise at least one input based on complementary base pair formation. At least one output may comprise an oligonucleotide.

The number of inputs may be at least two. The gate may be a logical AND gate, comprising at least two inputs, and being in a logical on state only if all inputs are in the same one of two states. The gate may be a logical AND NOT gate, comprising two inputs, and being in a logical on state if and only if one input is in a certain one of two states.

The logic gate may have one input, and form a logical NOT gate, being in a logical on state if the input is in a certain one of two states. The logic gate may comprise more than two inputs, wherein the gate is in a logical on state if at least one constituent stem-loop is in an open or closed state.

The logic gate may comprise a substrate binding region, wherein substrate binding is inhibited when the stem-loop is in the closed state. Alternatively, the substrate binding may be inhibited when the stem-loop is in the open state.

The gate may be a logical sensor gate, wherein an input is transduced into an output.

The logic gate may have a catalytic core region, wherein the stem-loop is attached to the catalytic region of the gate.

The gate may be a logical NOT gate.

According to another aspect of the invention, the logic gate may be arranged and used to detect a disease marker, wherein the disease marker has been translated into an oligonucleotide. The logic gate may be arranged and used to signal a disease marker, wherein the disease marker has been translated into an oligonucleotide.

According to another aspect of the invention, a plurality of logic gates of the type described above is provided, wherein the output of one gate is arranged as the input of another gate. The product of one gate may be arranged to be the input of another gate.

A plurality of gates may have a common substrate. The substrate of one gate may be the input of another gate.

The gates may operate in implicit OR fashion and form a logical OR gate. The gates may operate in implicit OR fashion and form a logical EXCLUSIVE OR gate. The gates may operate in implicit OR fashion and form a logical NAND gate. A plurality of logic gates may be arranged as a half adder. A plurality of logic gates may be arranged as a full adder.

According to another aspect of the invention, a logic gate performing a catalytic function as a logic operation is provided, said gate having at least one input and at least one output, said gate providing an output having a characteristic which depends on a characteristic of the input, said output characteristic being sufficient to be provided as an input characteristic to a second logic gate.

The gate may have at least two inputs. The logic operation may be AND. The logic operation may be XOR. The logic operation may be a sensing operation and the gate may be a YES gate. The gate may comprise a deoxyribozyme. The gate may comprise a ribozyme.

The logic gate may comprise peptide nucleic acid. The logic gate may comprise DNA. The logic gate may comprise RNA. The DNA may comprise natural DNA. The DNA may comprise synthetic DNA. The RNA may comprise natural RNA. The RNA may comprise synthetic RNA. The logic gate may comprise both natural and synthetic nucleotides.

The logic gate may further comprise a second logic gate, said second logic gate receiving as an input the output of the first logic gate.

According to another aspect of the invention, a method of performing a logical operation is provided using a logic gate having catalytic activity, at least one input, and an output capable of at least two different output states, said states depending on the catalytic activity of the gate, said logic gate further comprising at least one oligonucleotide and at least one stem-loop which controls the gate catalytic activity, which method comprises the steps of:

1) binding at least one input to a complementary loop within a stem-loop, to thereby open the corresponding stem, and

2) cleaving a substrate, wherein cleavage of the substrate indicates that a logical operation has been performed.

According to another aspect of the invention, a method of performing a logical operation is provided using a logic gate having catalytic activity, at least one input, and an output capable of at least two different output states, said states depending on the catalytic activity of the gate, said logic gate further comprising at least one oligonucleotide and at least one stem-loop which controls the gate catalytic activity, which method comprises the steps of:

1) binding at least one input to a complementary loop within a stem-loop, to thereby open the corresponding stem, and

2) inhibiting cleaving of a substrate, wherein inhibition of the cleavage of the substrate indicates that a logical operation has been performed.

According to another aspect of the invention, a method of performing a logical AND operation is provided using a logic gate having catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:

1) binding at least one input to a complementary loop within a stem-loop, to thereby open the corresponding stem, and

2) cleaving a substrate, wherein cleavage of the substrate indicates that a logical AND operation has been preformed.

According to another aspect of the invention, a method of performing a logical AND operation is provided using a logic gate having catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:

1) binding at least one input to a complementary loop within a stem-loop, to thereby open the corresponding stem, and

2) inhibiting cleavage of a substrate, wherein inhibition of the cleavage of the substrate indicates that a logical AND operation has been performed.

According to another aspect of the invention, a method of performing a logical AND NOT operation is provided using a logic gate having catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:

1) binding an input to a complementary loop within a stem-loop, in the absence of binding of other inputs, to thereby open the corresponding stem, and

2) cleaving a substrate, wherein cleavage of the substrate indicates that a logical AND NOT operation has been performed.

According to another aspect of the invention, a method of performing a logical AND NOT operation is provided using a logic gate having catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:

1) binding an input to a complementary loop within a stem-loop, in the absence of binding of other inputs, to thereby open the corresponding stem, and

2) inhibiting cleavage of a substrate, wherein inhibition of the cleavage of the substrate indicates that a logical AND NOT operation has been performed.

According to another aspect of the invention, a method of performing a logical NOT operation is provided using a logic gate having a catalytic region, at least one input, and an output capable of at least two different output states, said states depending on the catalytic activity of the gate, said logic gate further comprising at least one oligonucleotide and at least one stem-loop which controls the gate catalytic activity, which method comprises the steps of:

1) binding an input to a loop complementary to a stem-loop, in the absence of binding of other inputs, to thereby change the configuration of the catalytic region of the gate, and

2) cleaving a substrate, wherein the cleavage of the substrate indicates that a logical NOT operation has been performed.

According to another aspect of the invention, a method of performing a logical NOT operation is provided using a logic gate having a catalytic region, at least one input, and an output capable of at least two different output states, said states depending on the catalytic activity of the gate, said logic gate further comprising at least one oligonucleotide and at least one stem-loop which controls the gate catalytic activity, which method comprises the steps of:

1) binding an input to a loop complementary to a stem-loop, in the absence of binding of other inputs, to thereby change the configuration of the catalytic region of the gate, and

2) inhibiting cleavage of a substrate, wherein inhibition of the cleavage of the substrate indicates that a logical NOT operation has been performed.

According to another aspect of the invention, a method of performing a logical EXCLUSIVE OR operation is provided, which comprises performing a logical AND NOT operation with a plurality of logic gates having a common substrate, wherein cleavage of-the substrate indicates that a logical EXCLUSIVE OR operation has been performed.

According to another aspect of the invention, a method of performing a logical EXCLUSIVE OR operation is provided, which comprises performing the logical AND NOT operation with a plurality of logic gates having a common substrate, wherein inhibition of cleavage of the substrate indicates that a logical EXCLUSIVE OR operation has been performed.

In any of the methods, the stem-loop may comprise an oligonucleotide. The oligonucleotide may comprise a peptide nucleic acid.

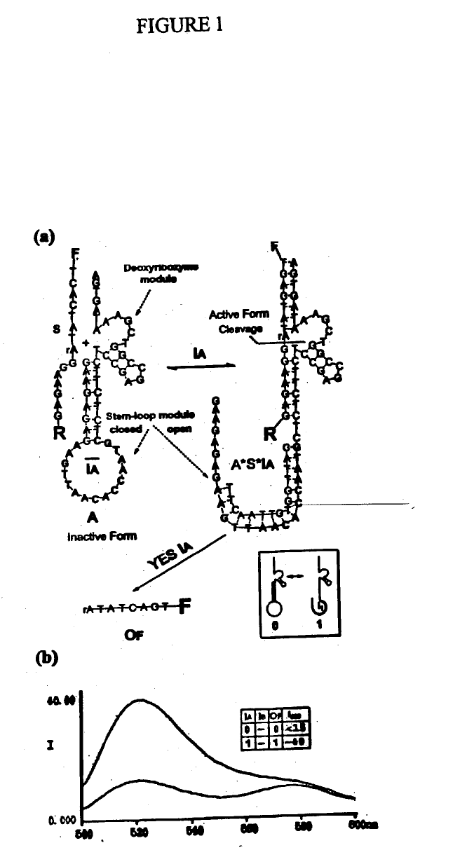

According to the invention, two oligonucleotides IA and IB as inputs for logic gates, and a cleaved product oligonucleotide OF as an output (FIG. 1). Their presence indicates an input/output of 1 and their absence an input/output of 0. Additionally, the catalytic cleavage of substrate S results in an increase in fluorescence, in order to facilitate detection of output in homogenous solution. The invention provides the basic set of NOT ( [symbol] ) and AND(¹⁶) \hat{ }) gates, followed by a combination of two deoxyribozymes that behaves as an exclusive OR¹⁷ (v or XOR) gate¹⁸.

Deoxyribozymes with various catalytic abilities have been developed with the advent of selection and amplification procedures⁸. For the purpose of demonstrating computational elements based on deoxyribozymes, two previously reported deoxyribozymes named 12E¹⁹ and 8-17²⁰ were chosen. Both catalysts cleave the phosphodiester backbone of a chimeric substrate S at the site of a single ribonucleotide (rA) embedded in a deoxyribonucleotide framework. The single ribonucleotide was used during the selection process to ensure a defined cleavage site. Importantly, the selection process to generate similar deoxyribozymes is well developed; should the need arise, multiple additional deoxyribozymes with different substrates can be isolated within weeks.

As demonstrated in previous experiments⁹, when oligonucleotide S is double end-labeled with a fluorescein donor (F) at the 5′ terminus and a tetramethylrhodamine acceptor (R) at the 3′ terminus, cleavage of S by deoxyribozymes results in an approximately tenfold increase is (^{15, 21}) in fluorescein emission intensity at 520 nm (λ_{exc}=480 nm), as a consequence of separation of donor from the acceptor.

Of the two deoxyribozymes used here, in original 8-17 is more active with a reported turnover of around 1 min⁻¹, in comparison to 0.04 min⁻¹ turnover of the original 12E.²² However, the catalytic core of the 8-17 is fixed and the internal loop (AGC) cannot be replaced with extended sequences. In contrast, internal loop of 12E (GAA) can be replaced with an arbitrary sequence.

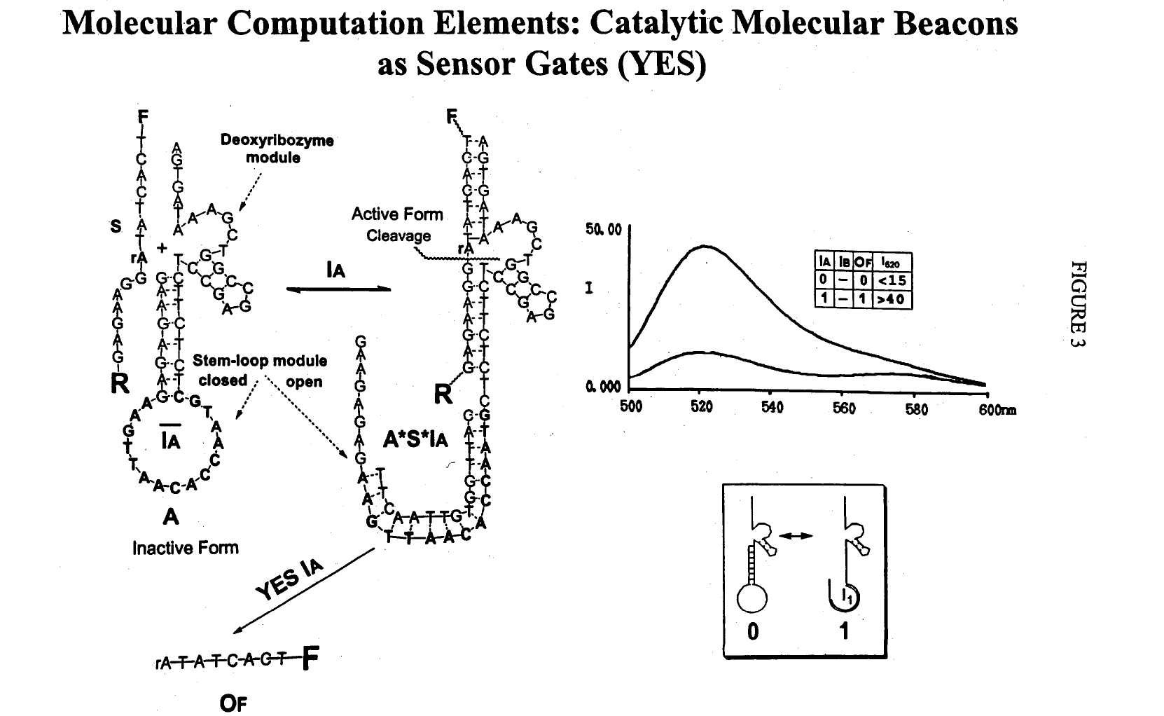

One of the important characteristics of catalytic oligonucleotides is the ability to design them modularly⁸ by combining controlling elements and catalytic regions. Indeed, by applying modular design, stem-loop controlling elements (inspired by molecular beacons²³) were used to construct deoxyribozymes allosterically promoted by oligonucleotides (i.e. catalytic molecular beacons^{15a}, FIG. 3). Such stem-loops are closed (self-hybridized) in the absence of oligonucleotide input complementary to the loop region; however, in the presence of input complementary to the loop they undergo stem opening. In order to build molecular scale computation elements making use of this design, stem-loop controlling elements were combined with substrate recognition arms, but the non-conserved loop of 12E was targeted to possibly achieve negative allosteric regulation by oligonucleotides. The attachments of single stem-loops to deoxyribozymes would produce single-input sensor gates, like YES and NOT, while attachments of more than one stem-loop would lead to the dual-input computation elements, like AND and XOR.

### Sensor and NOT Gates

Single-input sensor gates (sometimes referred to as YES gates in chemical literature) directly transduce oligonucleotide input into output (i.e. 1→1; 0→0)^{15a}. For example, in the gate A (FIG. 3) 8-17 was combined with a stem-loop (anti-IA or \overline{I_{A}}) complementary to IA. The stem-loop inhibits the catalytic module through overlap of the stem with the 5′ substrate recognition domain of the deoxyribozyme^{15a}. Hybridization of IA to the complementary loop opens the stem, reverses intramolecular competitive inhibition to allow binding of substrate to proceed. A solution containing two sensor gates with different inputs, but the same output oligonucleotide would behave as an implicit OR gate (not shown), which is active when at least one of the two inputs is present.

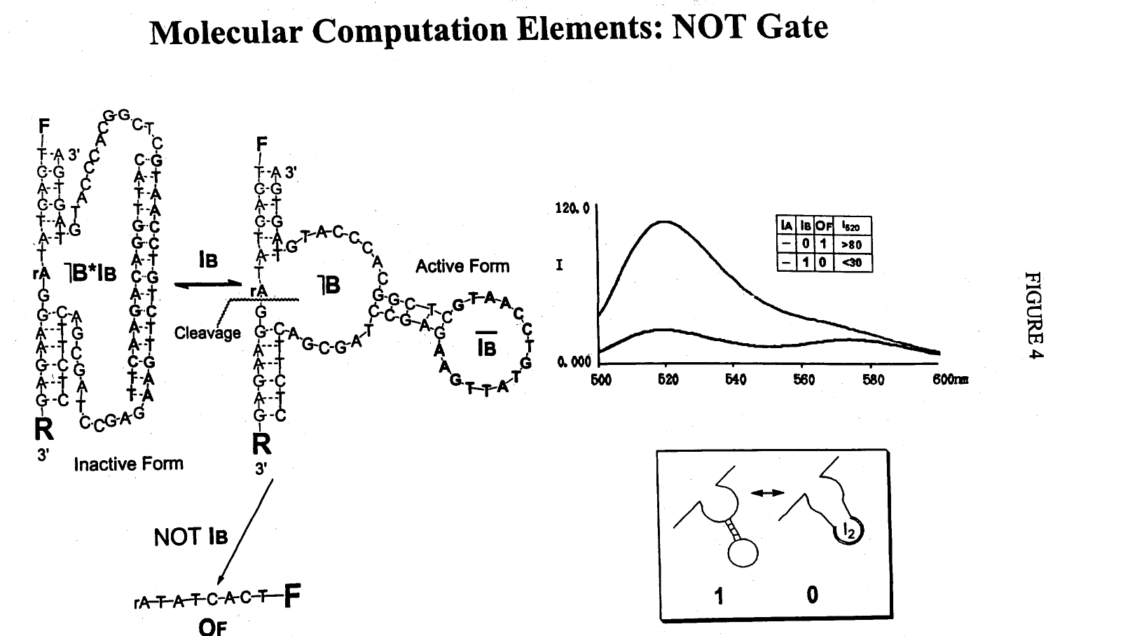

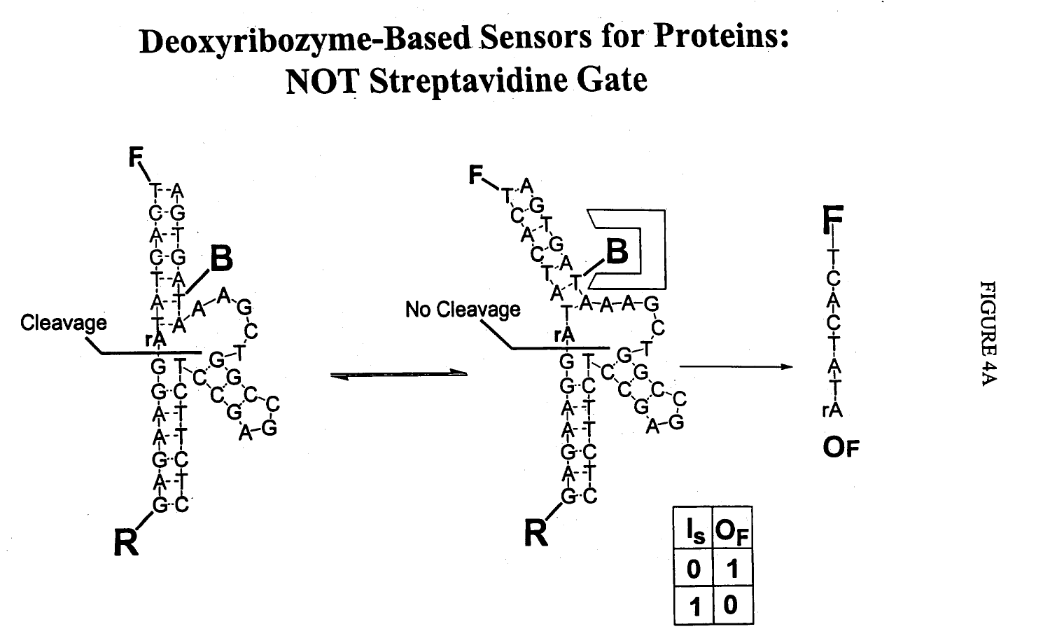

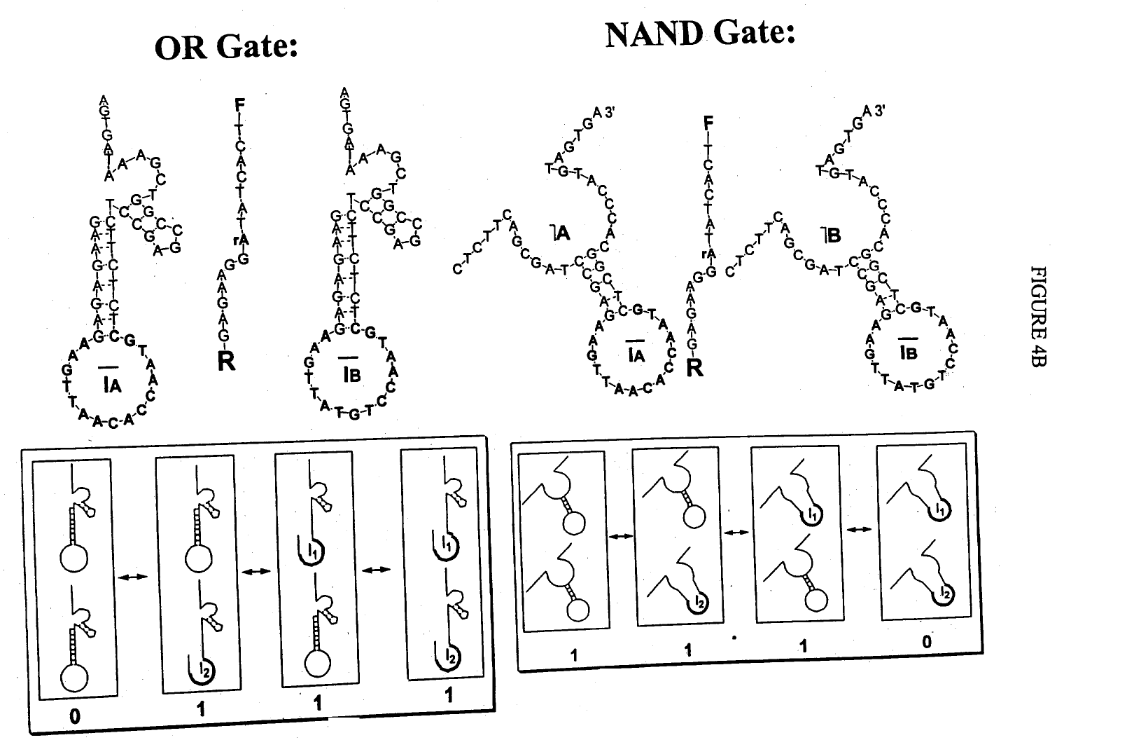

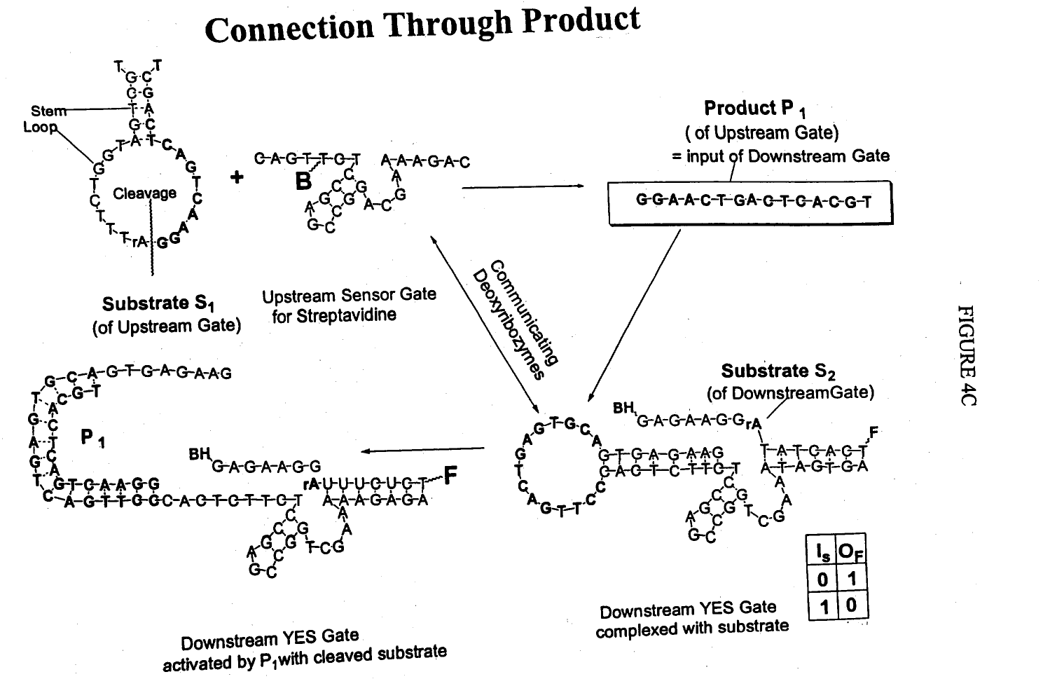

Single-input NOT gates invert any input data (i.e. 0→1; 1→0). To perform this function, the deoxyribozyme [symbol] B is introduced that is inhibited by a specific oligonucleotide input, IB (FIG. 4). The NOT gate is constructed by replacing the non-conserved loop of the 12E catalytic core with a stem-loop sequence complementary to IB. Hybridization of IB with the anti-IB opens the required stem structure of the core, distorting its shape and inhibiting its function. Unlike the behavior of YES gate A, where a complementary input causes a promoting effect based on the reversal of intramolecular inhibition, an input to [symbol] B causes intermolecular inhibition by creating a ternary complex ( [symbol] B*S*IB) unable to cleave the substrate.

As observed through changes in fluorescence (FIG. 4) the presence of IB is translated into the absence of OF, and vice versa, the absence of IB yields the presence of OF. NOT gates are less discriminatory in their interactions with mismatched oligonucleotides, and there is some mild inhibition by a triple mutant IA²⁴ (Supporting Information).

Importantly, two NOT gates with different input oligonucleotides and the same output oligonucleotide operating in parallel behave as an implicit NAND gate (not shown), based on DeMorgan's laws: [symbol] A v [symbol] B= [symbol] (A\hat{ }B).

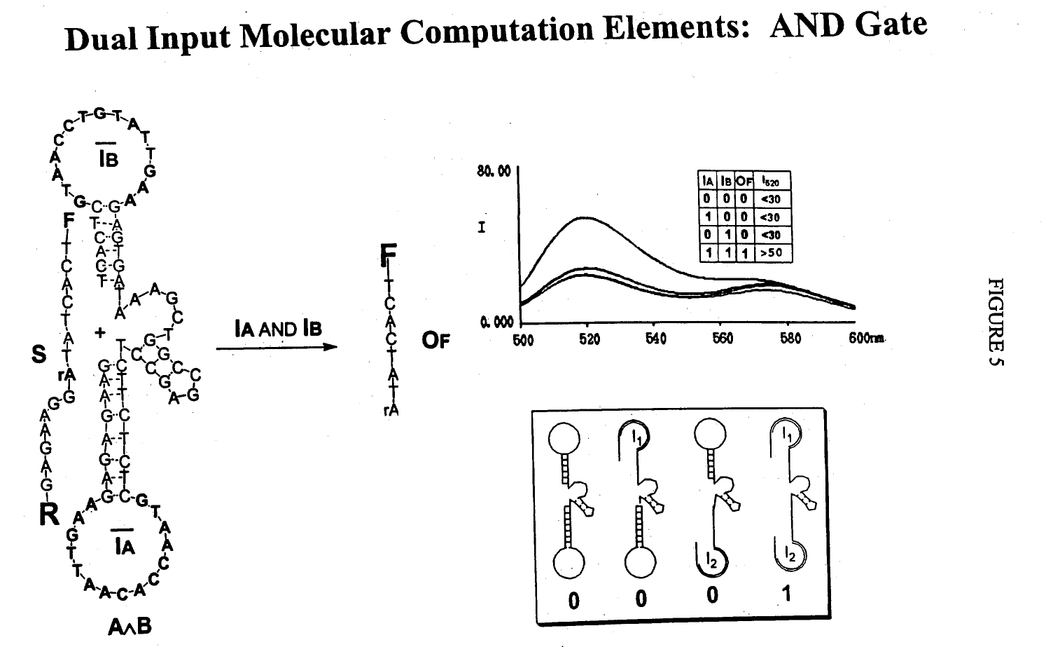

AND gates: The invention provides an AND gate that independently recognizes two inputs and provides output product only in the presence of both. Relying on the fully modtilar nature of catalytic molecular beacons, previously firmly established^{15a}, a controlling element is attached to each end of a single catalyst (8-17) to obtain A\hat{ }B. In this design, in the absence of its proper input either of the attached stem-loop structures would independently inhibit output formation. As shown in FIG. 5, in the absence of IA the 5′ substrate-recognition arm is blocked through an intramolecular hybridization that forms the stem of the anti-IA loop; analogously, in the absence of IB the 3′ substrate-recognition arm is blocked through intermolecular hybridization with the stem of the anti-IB loop. Only upon hybridization of both loops to complements (inputs) will both stems be opened, allowing recognition of S and its catalytic cleavage.

FIG. 5 illustrates fluorescence of a solution of A\hat{ }B and S with different combinations of oligonucleotide inputs. Fluorescence emission at 520 nm remains near background (substrate only) when only IA or IB is present, increasing only when both inputs are present. Therefore, A\hat{ }B behaves as an AND gate, using oligonucleotides IA and IB as inputs and providing oligonucleotide OF as an output.

XOR systems: As described above, an implicit OR gate could be constructed from two sensor gates with different inputs, but the same output oligonucleotide and this gate is active when at least one of the two inputs is present. A catalytic XOR (eXclusive OR) gate, however, must be active only when one (and only one) input is present. This is perhaps the most difficult dual-input gate to construct, because under one set of circumstances an input must trigger an output, while under another set of circumstances the very same input must inhibit the same output. To solve this problem, XOR was formed as a two-component system: Two groups of gates would operate in an implicit OR fashion, each group having identical substrates; however, deoxyribozymes of each group would be active in the presence of one input, but inactive upon addition of a second input. Importantly, the same input, which activated one group of deoxyribozymes, would be the deactivating input of the second group, and vice versa.

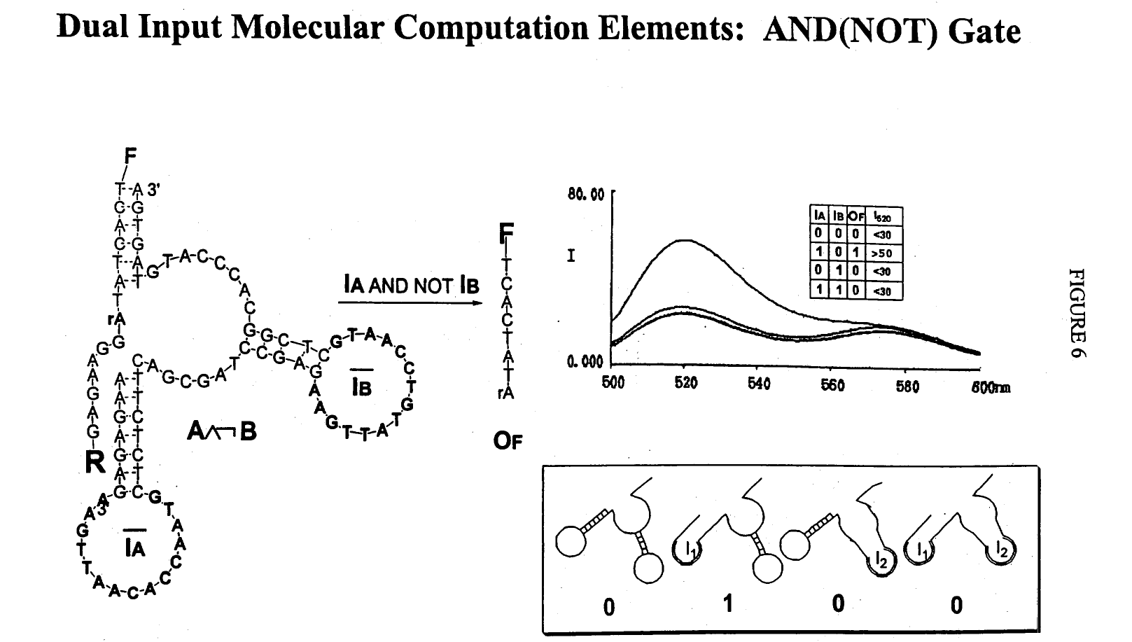

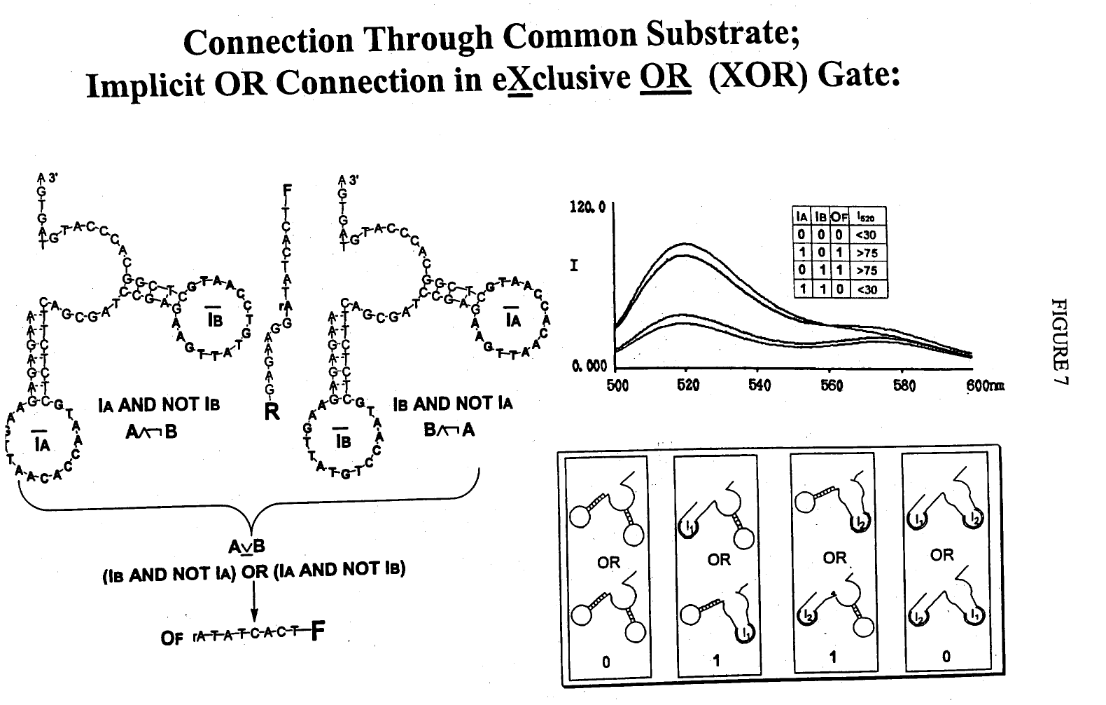

Accordingly, YES and NOT gates were combined in a single molecule to construct A\hat{ } [symbol] B (A AND NOT B, FIG. 6). A stem-loop recognizing IA was attached to a position at the 5′-end (where it inhibits the catalysis, as in an YES gate), and a stem-loop recognizing IB to the internal position of the 12E catalytic motif (where it does not influence catalysis without an input, as in a NOT gate). Thus, A\hat{ } [symbol] B is inhibited by the 5′ stem-loop when IA is absent, but is also inhibited by an open internal stem in the presence of IB. This gate is active only in the presence of IA and in the absence of IB, as can be seen in the FIG. 6. Deoxyribozyme B\hat{ } [symbol] A (B AND NOT A, not shown separately, please see FIG. 7) was constructed, in an analogous manner. A stem-loop recognizing IB was attached to the 5′ end where it inhibits catalysis, and a stem-loop complementary to IA was placed in an internal position of the 12E catalytic motif. Thus, B\hat{ } [symbol] A behaves in the opposite manner of A\hat{ } [symbol] B: it is active only when IB is present and IA is absent.

Present together in solution in an implicit OR arrangement A\hat{ } [symbol] B and B\hat{ } [symbol] A behave as a single XOR gate, AvB, that uses IA and IB as inputs and OF as an output. As seen in FIG. 7, AvB shows no increase in fluorescence in the absence of, or in the presence of, both inputs, while the presence of only IA or IB yields an increase in fluorescence.

### Discussion

Others have reported an AND gate-like operation using nucleic acid catalysts able to sense two small molecules in solution²⁵, (or one special case oligonucleotide and one small molecule²⁶). However, the present invention provides deoxyribozyme-based logic gates able to analyze two input oligonucleotides and operate as NOT, AND, and XOR gates with an oligonucleotide output. Because the set of enzyme-based logic gates described here includes the basis <NOT, AND>, it will suffice to generate any Boolean function, subject only to practical constraints of specific detection and the ability to serially connect the gates. Consequently, arbitrary binary arithmetic circuits can be implemented by using logic gate representations that are standard in computer engineering²⁷. For example, a half-adder takes two bits of input (IA and IB) to produce as outputs a sum digit and a carry digit. Thus a solution containing logic gates described herein, an XOR gate as the sum digit and an AND gate with a different substrate as the carry digit, would allow the simplest addition (1+1), as has been elegantly described for logic gates based on ion sensors²⁸.

The modular design of gates, demonstrated herein clearly by two deoxyribozymes with switched loops operating in parallel as an XOR gate, points to the generic nature of the constructs; i.e. almost any nucleic acid sequences of sufficient length can be now considered for an input. Necessary caveats to such generality include ensuring that: (i) input sequences are not complementary to entities in solution other than their beacon loops; (ii) one input oligonucleotide corresponds to a single beacon loop; (iii) input oligonucleotides do not form stable secondary structures; (iv) one deoxyribozyme motif cleaves only one substrate motif. Although these conditions limit the maximum number of deoxyribozymes that can operate in parallel in solution, proposed applications require only a limited number of serial and parallel operations. For example, in order to streamline the concurrent detection of four molecular disease markers into a single output, e.g. decision to release cytotoxic compound, only two parallel AND gates (to sense the markers) are serially connected to a third AND gate. Even for the full adder, not more than about 20 deoxyribozymes would be needed. In comparison, preliminary investigations show that tens of thousands of oligonucleotides can be constructed to form a compatible set that satisfies the constraints listed above²⁴.

Demonstrated behavior of logic gates is fully digital. Thus, an AND gate in the absence of both inputs, or in the presence of only one input, is indistinguishable from the complete absence of deoxyribozymes, i.e. the background cleavage of the substrate. The interactions of stem-loops (like in molecular beacons) with an excess of complementary oligonucleotides occur rapidly, within seconds²⁹; consequently, upon sensing activating inputs, deoxyribozymes that are part of logic gates are immediately ready to proceed with catalytic activity. Despite almost instant activation, the analysis of an output was perform after 12 hours. Such extended incubation periods are the result of decisions to use homogenous detection and to stress the catalytic nature of the process under multiple substrate turnover conditions³⁰. These choices necessitate the large excess of substrate causing the high background fluorescence. Electrophoretic methods of product detection would be able to detect digital activity after several minutes, yet would loose the simplicity of homogenous detection. Digital behavior was detected in fluorogenic assays after ten minutes or less under different conditions³¹.

The multiple turnover conditions are also important, as the present system is believed to be the first example of a full set of artificial enzymatic logic gates³². The enzymatic nature of gates ensures that the output fan out will not be the major issue in potential applications where serial connections of deoxyribozymes are needed.

### Operation of Computation Elements in Parallel

In a half-adder an AND gate is used for the carry digit, while an XOR gate yields the sum digit. Therefore, a combination and AND and XOR gates would allow the addition of 1+1. discussed above is an AND gate and a combination of two gates that operates as an XOR gate. Unfortunately, these gates could not operate independently in parallel, because they were constructed from deoxyribozymes that cleave the same product. Thus, one can choose the second group of deoxyribozymes. One can use, aside from E6 26, 8-17^{27,28} deoxyribozyme for the construction of a new AND gate.

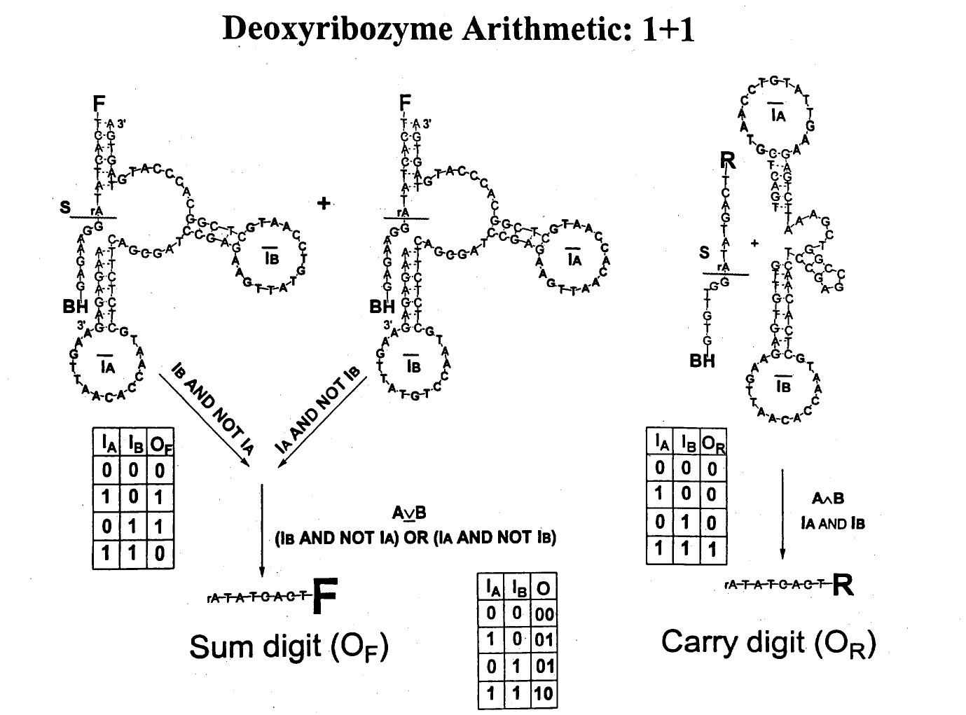

The exact mixture of oligonucleotides that will behave as a half adder is described in FIG. 8. The two deoxyribozymes operating as the XOR gate will be active (output 1) if only oligonucleotide I_{A} or I_{B} is present, but inactive if both are present. This is because omission of one input oligonucleotide will result in the activation of only one set of the deoxyribozymes of the XOR gate (1+0 or 0+1=01), while omission or presence of both inputs will leave both deoxyribozymes of the XOR gate inactive (0+)=00 or 1+1=00)). In contrast, the AND gate providing the carry digit will be active (output 1) only if both input oligonucleotides are present (1+1=10).

The significance of the half-adder experiment is multiple: first, the simplest arithmetical operation (i.e. adding 1+1) using artificial enzymes. Second, it provides independent operation of deoxyribozymes in parallel without interference. Third, because the output of these gates will be connected to a fluorescent readout, multicolor detection with deoxyribozymes is provided, a significant aspect of future diagnostic applications.

### Operation of Computation Elements in Series

### 1. Sensor and Logic Sates Connected to YES Gates

As explained above, solution-based molecular computation elements that use optical outputs cannot be employed for complex information processing. Deoxyribozyme-based logic gates, however, use oligonucleotides as both primary output (using changes in fluorescence for the most convenient readout) and input. Thus, two gates “in series” could communicate, if the product of an upstream gate would activate an appropriately coupled downstream gate. However, in order to ensure that the substrates of one gate do not inappropriately act as inputs for downstream gates, oligonucleotide products must be sufficiently different from the substrates that yielded them. One possibility is to use ligase deoxyribozymes that would assemble correct oligonucleotide sequences, but ligases are usually significantly larger enzymes (with one apparent exception) and therefore less practical. Substrate-product couples developed for phosphodiesterase deoxyribozymes in which only products will be able to activate downstream gates.

Oligonucleotide substrates of the upstream gates constrained in stable stem-loop structures were used. Downstream gates would not be activated by these substrates. The stretch of the substrate is tied in the stem and is unavailable for the Watson-Crick binding with an input loop of the downstream gate. However, the cleavage of the structured substrate in the central region of the loop would release two linear products that can each activate downstream gates. Initial results (Supporting Material, chembioChem) indicate that oligonucleotides tied in stem-loop structures are viable substrates for 8-17 (27, 28) and E6 (26) deoxyribozymes, including their analogs with stem-loop structures imposing allosteric control. This approach will be optimized through testing various substrate designs in the experiments in which the streptavidine element (NOT streptavidine gate) will be connected to a YES oligonucleotide gate. Next the connection of two AND gates to a third AND gates (not shown), will be examined in a network sensitive to the presence of four oligonucleotides. If necessary, it is possible to perform a reselection process that would optimize cleavage rates of the conformationally restricted substrates and minimize the background (spontaneous) cleavage of these substrates. It is also possible to increase the loop size to increase rates.

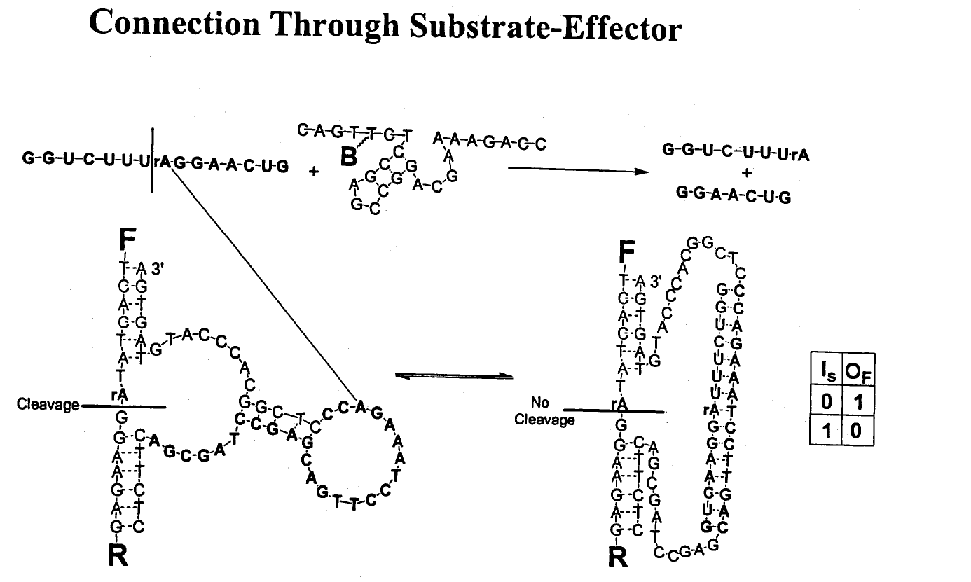

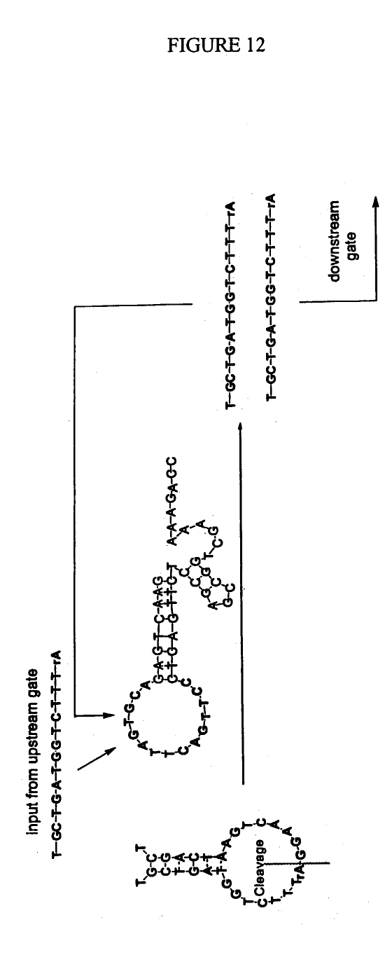

Two types of communications between upstream gates and downstream NOT gates were studied. First is essentially the same as described for YES gates (i.e. substrates are confined into stem-loop structures) and, as such, will not be specifically discussed any further. This type of connectivity has to be coupled to clocking function (see FIG. 12). The second type of connection is more direct. In it substrates were used that are allosteric inhibitors of NOT gates (FIG. 10): as substrate is destroyed, the NOT gate is activated. In the example NOT streptavidine sensor gate is connected into the NOT oligonucleotide gate, resulting in streptavidine NOT gate with translated output. This type of connection will have limited applications within computational modules of deoxyribozyme networks; however, it is of potential importance in translating oligonucleotide outputs of computational modules into small molecule outputs of drug delivery modules.

There are two issues be addressed before more complex demonstrations of communication between elements and serial connections. First, oligonucleotide products of upstream gates must be sufficiently different from their substrates, in order to ensure that only products act as inputs for downstream gates. It is relevant in this context that stem-loop structures are able to act as substrates for deoxyribozymes^{15a}. Upon cleavage, these molecules reveal an oligonucleotide stretch previously unavailable for Watson-Crick base pairing. As a consequence of the design, according to the invention downstream NOT gates would remain active until sufficient inhibitory product has accumulated. This problem, however, also appears in electronic circuits and synchronization of elements is achieved through clocking function. Similar strategies can be devised for molecular scale computation elements.

### The Clocking Function with NOT Gates

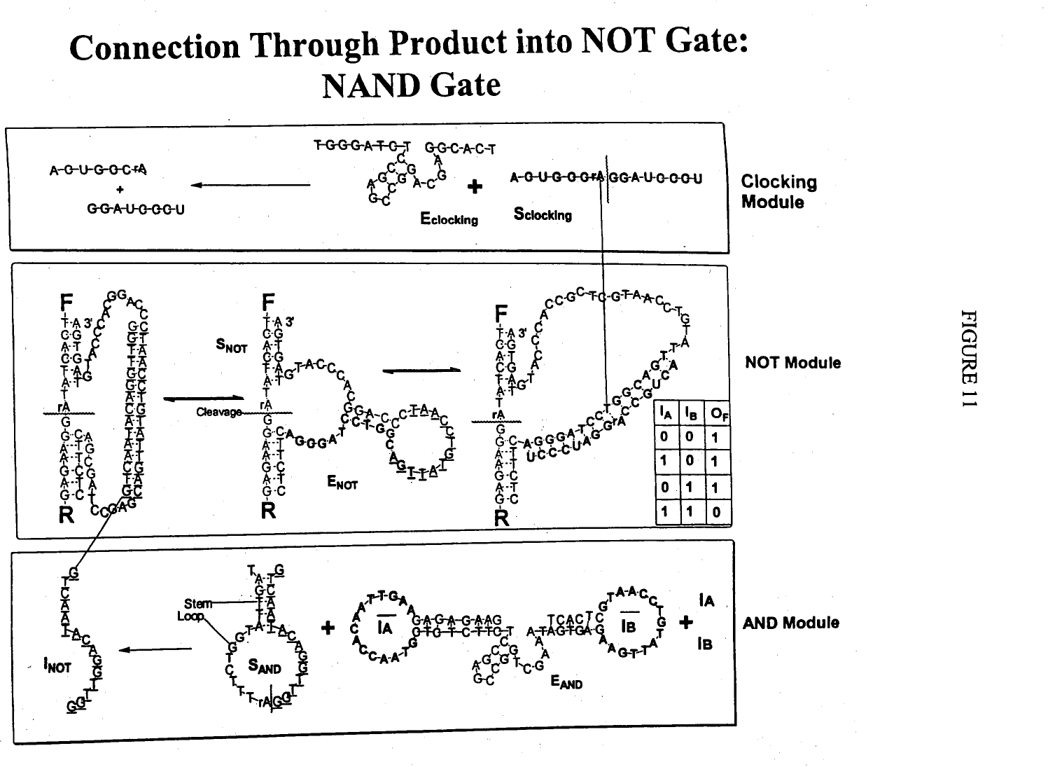

A solution of NOT gates remains active until a sufficient amount of inhibitory product has accumulated to deactivate it. In order to construct more complex arithmetic circuits, it will be necessary to synchronize (clock) the introduction of active NOT gates with the accumulation of a product inhibitor. This function is analogous to the gate synchronization or clocking in electronic circuits. For deoxyribozymes, the clocking function can be directly introduced by the presence of clocking inhibitory oligonucleotide that is cleaved at a certain rate by a clocking deoxyribozyme operating in parallel to the NOT gate (FIG. 11). The length and composition of the clocking deoxyribozyme/oligonucleotide couple can be experimentally optimized. The NOT gate will become active only upon drop in the concentration of clocking inhibitor below one equivalent, unless another inhibitory oligonucleotide is formed by the upstream gate. In this way, the upstream gate will communicate its status (i.e. active or not active) to the NOT gate. The amounts of clocking deoxyribozyme and its substrate would define the timing of NOT gates activity. An AND gate cn be connected into clocked NOT gates, to give an implicit NAND gate. While a NAND gate specifically could be constructed through two NOT gates operating in implicit OR fashion (2), the crucial principles necessary for the development of the more complex networks are provided.

### Amplification of the Signal through YES Gates with Feedback Loop

The next issue addressed is the ability to amplify signals going into downstream gates. While this will not be an important issue for less complex networks, in the next generation of decision-making in solution it may seriously impede or slow-down the process. The specific problem and solved here is the slow accumulation of activating inputs for downstream gates. This will be especially acute problem with AND gates, where sub-equivalent amounts of inputs will be further diluted by statistical distribution between two stem-loops, which have to be activated simultaneously. This problem can be solved by introducing deoxyribozyme-chain reactions, which would be able to amplify initially weak signals and achieve saturated activation of downstream gates. Deoxyribozyme-chain reactions are based on stem-loop substrates where one half of the substrate would be identical to the input (FIG. 12). Thus each cleavage would produce another activating input, starting a chain reaction that is similar to radical chain reactions. One may have to optimize the structure of substrate, especially stem and loop lengths to minimize background cleavage reaction, which would be observed as strong noise.

The deoxyribozyme-chain reaction is significant. Sensitivity of this system has been in low-to-mid nanomolar range. Coupling of the chain reaction to the catalytic molecular beacons is likely to increase sensitivity by several order of magnitude, making this system probably the most sensitive non-PCR based method for detection of oligonucleotides. Importantly, with the development of allosteric ribozymes, any small molecule or protein input can be ampliefied into multiple copies of oligonucleotides, and each could act as an initiator for a chain reaction. With multicolor detection systems that could be set up through achievement of the aim 1, this could lead to highly sensitive multiplex assays.

### Construction of Analytical Networks with Three Inputs

The ultimate goal of this project is the development of practical application of decision-making networks in sensor arrays and intelligent drug delivery systems. Along these lines, a network of deoxyribozymes can be constructed that is capable of multiplex analysis of solution and that releases a signal only if certain criteria are satisfied. These networks will combine DNA computation function with deoxyribozyme sensors. The goal will be to demonstrate that the presence or absence of three analytes (e.g. one protein, one small molecule and one oligonucleotide) can trigger a specific reaction of the deoxyribozyme network. One can demonstrate eventually all possibilities, wherein presence of all three (input 111), absence of one (110), two (100) or three analytes (000) will either trigger the production of fluorescence product (output 1) or inhibit formation of fluorescence product (output 0).

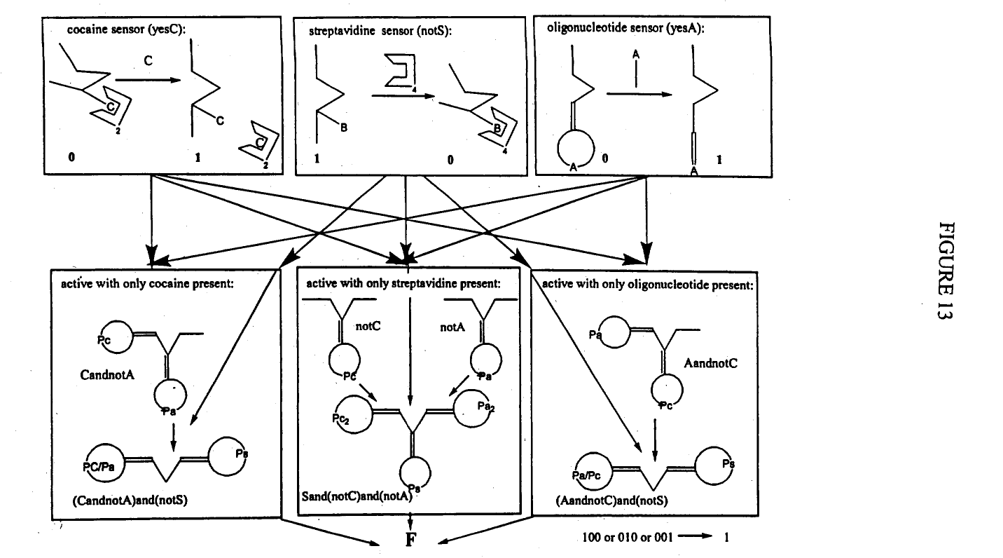

In model networks, presence of cocaine, streptavidine and a15-mer oligonucleotide can be detected. In the simplest design, which does not require any synchronization (not shown), a network can be made that will produce a fluorescent output if cocaine and oligonucleotides are present, and streptavidine is absent. Next, other representative networks can be constructed. Provided here is a schematic representation (FIG. 13) of a network that releases fluorescent product if any one of the three analytes is present and the other two are absent. This network will represent a key step toward construction of full adder based on deoxyribozymes, as it is a part of the sum digit.

Targeted applications do not require reversibility. However, gates are fully reversible: removal of input oligonucleotides resets them to the initial states. In instances where gates may be attached to surfaces(³³) removal of inputs can be achieved by washing; when in solution, input complements could be added, as is standard in state-of-the-art DNA-based machines³⁴.

Lastly, results reported herein provide one possible explanation as to how metabolic control and quorum sensing were organized in the early RNA-based organisms³⁵, the chemistry of which is postulated to have focused on the production and degradation of various oligonucleotides. For example, networks of AND, NOT and XOR gates could have been used to monitor the balance of specific oligonucleotide (metabolic) products; accumulation of these above a certain level could have activated or deactivated catabolic pathways.

### Conclusion

Conjunction (AND), disjunction (OR) and negation (NOT) are the building blocks of logic: all other operations, no matter how complex, can be obtained by suitable combination of these. A set of molecular scale logic gates have successfully constructed that encompasses these basic functions. The switches are based on deoxyribozymes that use oligonucleotides as both inputs and output. The design of the control mechanism, based on the conformational changes of stem-loops, can be extended to any nucleic acid catalyst. Almost any group of oligonucleotides can be used to trigger the analytical function of these computation elements and a resultant presence (or absence) of fluorescent oligonucleotide product. Communication networks can be formulated between deoxyribozymes, and integrating recognition and analytical functions with therapeutic effects.

### Materials and Methods

### Materials

All oligonucleotides were made by Integrated DNA Technologies Inc. (Coralville, IA), and purified by HPLC or PAGE electrophoresis, except 15-mers IA and IB, which were used crude. Samples were dissolved in RNase and DNase free water, separated in aliquots and frozen at −20° C. until needed. All experiments were performed in autoclaved 50 mM HEPES, 1 M NaCl, pH=7.5 at room temperature. MgCl₂ was obtained from Sigma-Aldrich Co. (St. Louis, Mo.) and used as 200 mM autoclaved stock solutions in water.

Instrumental: All fluorescent spectra were obtained on Hitachi Instruments Inc. (San Jose, Calif.) F-2000 Fluorescence Spectrophotometer with Hamamatsu Xenon Lamp. Experiments were performed at the excitation wavelength of 480 nm and emission scan at 500-600 nm. Printouts of spectra were scanned and colors manually introduced in Adobe Photoshop 5.5.

Procedures: Logic gates (1 μM stock, 10 μL, final concentration 200 nM), oligonucleotides IA and IB (5 μM stock, 10 μL, final concentration 1 μM) and substrate (30 μM stock, 10 μL, final concentration 6 μM) were mixed in that order. For the “0” input buffer (10 μL) was used instead of I_{A} or I_{B}. Reactions were initiated after five minutes by the addition of Mg²⁺, (50 mM stock 10 μL final concentration 10 mM). After incubation at room temperature aliquots (5 μL) were diluted to 0.5 ML with HEPES buffer and transferred into a quartz semimicro-cuvette for spectrofluorometric analysis.

Supporting Information Available: 1. Fluorescence spectra for the reaction of [symbol] B gate in the presence of I_{A}, I_{B} and both oligonucleotides; 2. Rn values (E₅₂₀/E₅₇₀) for the catalytic cleavage by A\hat{ } [symbol] B in the presence of I_{A}, I_{B} and both oligonucleotides at ten, thirty and sixty minutes.

### References

1. a) Ball, P. Nature 2000, 406, 118-120 and references therein. b) Joachim, C.; Gimzewski, J. K.; Aviram, A. Nature 2000, 408, 541-548. For representative approaches to computation on the molecular scale and molecule-based electronic devices see: for small molecule computation elements and their integration in circuits: c) Metzger, R. M. Acc. Chem. Res. 1999, 32, 950-957. d) Donhauser, Z. J.; Mantooth, B. A.; Kelly, K. F.; Bumm, L. A.; Monnell, J. D.; Stapleton, J. J.; Price, D. W.; Rawlett, A. M., Allara, D. L.; Tour, J. M.; Weiss, P. S. Science 2001, 292, 2303-2307. e) Pease, A. R.; Jeppesen, J. O.; Stoddart, J. F.; Luo, Y.; Collier, C. P.; Heath, J. R. Ace. Chem. Res. 2001, 72, 11-20; f) for biological systems: Hayes, B. Am. Scient. 2001, 89, 204-209. and references therein. g) for single molecule transistors: Schoen, J. H.; Meng, H.; Bao, Z. Science 2001, 294, 2138-2140. h) for carbon nanotubes: Postma, H. W. C.; Teepen, T.; Yao, Z.; Grifoni, M.; Dekker, C. Science 2001, 293, 76-79.

2. For molecular computation approaches based on DNA: a) Adleman, L. M. Science 1994, 266, 1021. b) Quyang, Q.; Kaplan, P. D.; Liu, S.; Libchaber, A. Science 1997, 278, 446. c) for nanoassemblies of DNA: Mao, C.; LaBean, T. H.; Reif, J. H.; Seeman, N. C. Nature 2000, 407(6803) 493-496. d) for an automaton based on operations of restriction nucleases and ligases on DNA: Benenson Y.; Paz-Elizur, T.; Adar, R. Keinan, E.; Livneh, Z.; Shapiro, E. Nature 2001, 414, 430-434. For surface DNA computation: h) Wang, L.; Hall, J. G.; Lu, M.; Liu, Q.; Smith, L. M. Nat. Biotechnol. 2001, 19, 1053-1059 and references therein. i) Pirrung, M. C.; Connors, R. V.; Odenbaugh, A. L.; Montague-Smith, M. P.; Walcottt, N. G., Tollett, J. J. J. Am. Chem. Soc. 2000, 122, 1873-1882. j) hairpin computations: Sakamoto, K.; Gouzu, H.; Komiya, K.; Kiga, D.; Yokoyama, S.; Yokomori, T.; Hagiya, M. Science 2000, 288, 1223-1226.

3. a) for an example of a similar suggestion, i.e. that DNA can be used for smart drug delivery, see an issue of BioSystems dedicated to DNA-based computing, specifically: Yurke, B.; Mills, A. P.; Cheng, S. L. BioSystems 1999, 52, 165-174. b) For a suggestion that an AND gate (actually an AND NOT gate) can sense low glycogen and high glucose and release insulin see: Cox, J. C.; Ellington, A. D. Curr. Biol. 2001, 11, R336.

4. a) Tuerk, C., Gold, L. Science 1990, 249, 505-510. b) for small molecule SELEX: Ellington, A. D.; Szostak, J. W. Nature 1990, 346, 818-822.

5. mRNA disease signatures can be targeted by antisense technologies (ref. 7).

6. For homing with peptides see: a) Brown, K. C. Curr. Op. Chem. Biol. 2000, 4; 16-21. b) for tissue SELEX: Dinkelborg, L.; Hilger, C. -S.; Platzek, J. 1996 Ger. Offen. DE 4424922.

7. Hughes, M. D.; Hussain, M.; Nawaz, Q. et al. Drug Disc. Today 2001, 6, 303-14.

8. Soukup, G. A.; Breaker, R. R. Curr. Opin. Struct. Biol. 2000, 10, 318-325.

9. Stojanovic, M. N.; de Prada, P.; Landry, D. W. Nucleic Acids Res. 2000, 28, 2915-2918.

10. Robertson, M. P.; Ellington, A. D. Nat. Biotechnol. 2001, 19, 650-655.

11. a) Stojanovic, M. N.; de Prada, P.; Landry, D. W. J. Am. Chem. Soc. 2000, 122, 11547-11548. b) Stojanovic, M. N.; de Prada, P.; Landry, D. W. J. Am. Chem. Soc. 2001, 123, 11547-11548 and references therein.

12. For nucleic acid-triggered catalytic drug release see: Ma, Z.; Taylor, J. -T. Proc. Natl. Acad. Sci. USA 2000, 97, 1159-1163.

13. For an elegant work describing communication between fluorophores, see: Rayrno, F. M.; Giordani, S. Org. Lett.. 2001, 3, 1833-1836 and references therein.

14. Li, Y.; Breaker, R. R. Curr. Opin. Struct. Biol. 1999, 9(3), 315-323.

15. a) Stojanovic, M. N.; de Prada, P.; Landry, D. W. ChemBioChem 2001, 2, 411-415. b) for a different approach to allosteric control by oligonucleotides based on “maxizymes”, demonstrated in vivo, see: Kuwabara, T.; Warashina, M.; Taira, K. Curr. Opin. Chem. Biol. 2000, 4(3), 669-677 and earlier references therein.

16. For chemical systems performing AND logic operations see: a) Huston, M. E.; Akkaya, E. U.; Czarnik, A. W. J. Am. Chem. Soc. 1989, 111, 8735-8737. b) Hosseini, M. W.; Blacker, A. J.; Lehn, J. -M. ibid 1990, 112, 3896-3897. c) de Silva, A. P.; Gunaratne, H. Q. N.; McCoy, C. P. Nature 1993, 364, 42-44. d) id. J. Am. Chem. Soc. 1997, 119, 7891-7892. e) Iwata, S.; Tanaka, K. J. Chem. Soc. Chem. Com. 1995, 1491.

17. For molecular scale XOR gates see: a) Credi, A.; Balzani, V.; Langford, S. J.; Stoddart, J. F. J. Am. Chem. Soc. 1997, 119, 2679-2681. b) Pina, F.; Melo, M. J.; Maestri, M.; Passaniti, P.; Balzani, V. J. Am. Chem. Soc. 2000, 122, 4496-4498.

18. For integrated AND NOT (or “INHIBIT”) function see: de Silva, A. P.; Dixon, I. M.; Gunaratne, H. Q. N.; Gunnlaugsson, T.; Maxwell, P. R. S.; Rice, T. E. J. Am. Chem. Soc. 1999, 121, 1393-1394.

19. Breaker, R. R.; Joyce, G. F. Chem. Biol. 1995, 2, 655-660.

20. This deoxyribozyme was reported as 17E by a) Li, J.; Zheng, W.; Kwon, A. H.; Lu, Y. Nucleic Acids Res. 2000, 28, 481-488, but has the catalytic core identical to 8-17 previously reported by b) Santoro, S. W.; Joyce, G. F. Proc. Natl. Acad. Sci. USA 1997, 94, 4262-4266.

21. This number was found to be between 2 and 30 with different substrates, depending on their structure and ability to form dimers.

22. Intensive effort is in progress to improve turnover numbers of nucleic acid catalysts through selection with unnatural nucleotides: a) Santoro S, W.; Joyce, G. F.; Sakthivel, K.; Gramatikova, S.; Barbas, C. F. J. Am. Chem. Soc. 2000, 122, 2433-2439. b) Perrin, D., Garestier, T.; Helene, C. J. Am. Chem. Soc. 2001, 123, 1556-1563.

23. For traditional molecular beacons see: Tyagi, S.; Bratu, D. P.; Kramer, F. R. Nat. Biotechnol. 1998, 16, 49-53 and references therein.

24. Hamming distance in these oligonucleotide-based computation elements can be defined as number of mismatches that minimizes cross talk between two elements. Thus, at room temperature and high Mg²⁺ concentrations, for 15-mer oligonucleotides the Hamming distance can be realistically set at 3 for YES gates and 4 for NOT gates. For a detailed discussion of Hamming distances in the parallel DNA-based computation see: a) Marathe, A.; Condon, A. E.; Corn, R. M. Dimacs Workshop on DNA Based Computers V, June 1999, 75-89. b) Frutos, A. G., Liu, Q., Thiel, A. J.; Sanner, A. M. W.; Condon, A. E.; Smith, L. M.; Corn, R. M. Nucleic Acids Res. 1997, 25, 4748-4757.

25. Jose, A. M.; Soukup, G. A.; Breaker, R. R. Nucleic Acids Res. 2001, 29, 1631-1637.

26. Roberts, M. P.; Ellington, A. D. Nat. Biotechnol. 1999, 17, 62-66.

27. Edward J. McCluskey, “Logic Design Principles” Prentice-Hall 1986.

28. de Silva, A. P.; McClenaghan, N. D. J. Am. Chem. Soc. 2000, 122, 3965-3966.

29. Bonnet, G.; Tyagi, S.; Libchaber, A.; Kramer, F. R. Proc. Natl. Acad. Sci. U S. A. 1999, 96, 6171-6176.

30. Approximately 4-12 turnovers per enzyme occur in this period, depending on the gate, as calculated with the equation from our reference 15a.

31. For an example of AΛB, please see Supporting Information; for other conditions, see references 15a and 20a.

32. For an approach to enzymatic logic gates, see: Tuchman, S.; Sideman, S.; Kenig, S.; Lotan, N. Mol. Electron. Devices 1994, 3, 223-238.

33. Surface-based approaches to DNA computation are described in our references 3h, 3i, 24a, and 24b.

34. Yurke, B.; Turberfield, A. J.; Mills, A. P.; Simmel, F. C.; Neumann, J. L. Nature 2000, 406, 605-608.

35. Yarus, M. Curr. Opin. Chem. Biol. 2000, 3, 260-7.

I claim:

1. A logic gate comprising at least one input, at least one output, at least one oligonucleotide with catalytic activity and at least one stem-loop which controls the catalytic activity of the gate, wherein each said output is capable of at least two different output states, said states depending on the catalytic activity of the gate.

2. The logic gate of claim 1, wherein the configuration of at least one stem-loop determines the output state.

3. The logic gate of claim 2, wherein the gate has one input, and a first output state when the stem-loop is closed and a second output state when the stem-loop is open.

4. The logic gate of claim 3, wherein the first output state corresponds to a logical off and the second output state corresponds to a logical on.

5. The logic gate of claim 3, wherein the first output state corresponds to a logical on and the second output state corresponds to a logical off.

6. The logic gate of claim 1, wherein the output of the gate comprises a fluorescent readout.

7. The logic gate of claim 1, wherein the output of the gate comprises an electromagnetic readout.

8. The logic gate of claim 1, wherein the output of the gate comprises a material whose conductivity changes to indicate the output states.

9. The logic gate of claim 1, wherein the output of the gate comprises a material whose magnetization changes to indicate the outputstate.

10. The logic gate of claim 1, wherein the stem-loop comprises an oligonucleotide.

11. The logic gate of claim 1, wherein the oligonucleotide comprises a peptide nucleic acid.

12. The logic gate of claim 1, wherein at least one input comprises an oligonucleotide.

13. The logic gate of claim 1, wherein at least one output comprises an oligonucleotide.

14. The logic gate of claim 12, wherein the number of inputs is at least two.

15. The logic gate of claim 1, wherein the gate is a logical AND gate, comprising two inputs, and being in a logical on state only if both inputs are present.

16. The logic gate of claim 1, wherein the gate is a logical AND NOT gate, comprising two inputs, and being in a logical on state if and only if one input is present.

17. The logic gate of claim 1 comprising one input, wherein the gate is a logical NOT gate, being in a logical on state if the input is absent.

18. The logic gate of claim 1 further comprising a substrate binding region, wherein substrate binding is inhibited when the stem-loop is in the closed state.

19. The logic gate of claim 18, wherein the gate is a logical sensor gate, wherein an input is transduced into an output.

20. The logic gate of claim 1 further comprising a catalytic core region, wherein the stem-loop is attached to the catalytic region of the gate.

21. The logic gate of claim 20, wherein the gate is a logical NOT gate.

22. Use of the logic gate of claim 1 to detect a disease marker, wherein the disease marker has been translated into an oligonucleotide.

23. Use of the logic gate of claim 1 to signal a disease marker, wherein the disease marker has been translated into an oligonucleotide.

24. A plurality of logic gates of claim 1, wherein the output of one gate is the input of another gate.

25. A plurality of logic gates of claim 1, wherein the product of one gate is the input of another gate.

26. A plurality of logic gates of claim 1, wherein the gates have a common substrate.

27. A plurality of logic gates of claim 1, wherein the substrate of one gate is the input of another gate.

28. The plurality of logic gates of claim 26, wherein the gates operate in implicit OR fashion and form a logical OR gate.

29. The plurality of logic gates of claim 26, wherein the gates operate in implicit OR fashion and form a logical EXCLUSIVE OR gate.

30. The plurality of logic gates of claim 26, wherein the gates operate in implicit OR fashion and form a logical NAND gate.

31. A plurality of logic gates of claim 1 arranged as a half adder.

32. A plurality of logic gates of claim 1 arranged as a full adder.

33. A logic gate performing a catalytic function as a logic operation, said gate having at least one input and at least one output, said gate providing an output having a characteristic which depends on a characteristic of the input, said output characteristic being sufficient to be provided as an input characteristic to a second logic gate.

34. The logic gate of claim 33, wherein the gate has at least two inputs.

35. The logic gate of claim 33, wherein the logic operation is AND.

36. The logic gate of claim 33, wherein the logic operation is XOR.

37. The logic gate of claim 33, wherein the logic operation is a sensing operation and the gate is a YES gate.

38. The logic gate of claim 1 or claim 33, wherein the gate comprises a deoxyribozyme.

39. The logic gate of claim 1 or claim 33, wherein the gate comprises a ribozyme.

40. The logic gate of claim 33, further comprising a second logic gate, said second logic gate receiving as an input the output of the first logic gate.

41. A method of performing a logical operation using a logic gate comprising catalytic activity, at least one input, and an output capable of at least two different output states, said states depending on the catalytic activity of the gate, said logic gate further comprising at least one oligonucleotide and at least one stem-loop which controls the gate catalytic activity, which method comprises the steps of:
1) binding at least one input to a complementary loop within a stem-loop, to thereby open the corresponding stem, and
2) cleaving a substrate, wherein cleavage of the substrate indicates that a logical operation has been performed.

42. A method of performing a logical operation using a logic gate comprising catalytic activity, at least one input, and an output capable of at least two different output states, said states depending on the catalytic activity of the gate, said logic gate further comprising at least one oligonucleotide and at least one stem-loop which controls the gate catalytic activity, which method comprises the steps of:
1) binding at least one input to a complementary loop within a stem-loop, to thereby open the corresponding stem, and
2) inhibiting cleaving of a substrate, wherein inhibition of the cleavage of the substrate indicates that a logical operation has been preformed.

43. A method of performing a logical AND operation using a logic gate comprising catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:
1) binding at least one input to a complementary loop within a stem-loop, to thereby open the corresponding stem, and
2) cleaving a substrate, wherein cleavage of the substrate indicates that a logical AND operation has been performed.

44. A method of performing a logical AND operation using a logic gate comprising catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:
1) binding at least one input to a complementary loop within a stem-loop, to thereby open the corresponding stem, and
2) inhibiting cleavage of a substrate, wherein inhibition of the cleavage of the substrate indicates that a logical AND operation has been preformed.

45. A method of performing a logical AND NOT operation using a logic gate comprising catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:
1) binding an input to a complementary loop within a stem-loop, in the absence of binding of other inputs, to thereby open the corresponding stem, and
2) cleaving a substrate, wherein cleavage of the substrate indicates that a logical AND NOT operation has been performed.

46. A method of performing a logical AND NOT operation using a logic gate comprising catalytic activity, a plurality of inputs, and an output capable of at least two different output states, said states depending on the catalytic activity of the gate, said logic gate further comprising at least one oligonucleotide and at least one stem-loop which controls the gate catalytic activity, which method comprises the steps of:
1) binding an input to a complementary loop within a stem-loop, in the absence of binding of other inputs, to thereby open the corresponding stem, and
2) inhibiting cleavage of a substrate, wherein inhibition of the cleavage of the substrate indicates that a logical AND NOT operation has been performed.

47. A method of performing a logical NOT operation using a logic gate comprising a catalytic region, at least one input, and an output capable of at least two different output states, said states depending on the catalytic activity of the gate, said logic gate further comprising at least one oligonucleotide and at least one stem-loop which controls the gate catalytic activity, which method comprises the steps of:
1) binding an input to a loop complementary to a stem-loop, in the absence of binding of other inputs, to thereby change the configuration of the catalytic region of the gate, and
2) cleaving a substrate, wherein the cleavage of the substrate indicates that a logical NOT operation has been performed.

48. A method of performing a logical NOT operation using a logic gate comprising a catalytic region, at least one input, and an output capable of at least two different output states, said states depending on the catalytic activity of the gate, said logic gate further comprising at least one oligonucleotide and at least one stem-loop which controls the gate catalytic activity, which method comprises the steps of:
1) binding an input to a loop complementary to a stem-loop, in the absence of binding of other inputs, to thereby change the configuration of the catalytic region of the gate, and
2) inhibiting cleavage of a substrate, wherein inhibition of the cleavage of the substrate indicates that a logical NOT operation has been performed.

49. A method of performing a logical EXCLUSIVE OR operation, which comprises performing the logical AND NOT operation of claim 45 with a plurality of logic gates having a common substrate, wherein cleavage of the substrate indicates that a logical EXCLUSIVE OR operation has been performed.

50. A method of performing a logical EXCLUSIVE OR operation, which comprises performing the logical AND NOT operation of claim 46 with a plurality of logic gates having a common substrate, wherein inhibition of cleavage of the substrate indicates that a logical EXCLUSIVE OR operation has been performed.

51. The method of any one of claims 41-50, wherein the stem-loop comprises an oligonucleotide.

52. The method of any one of claims 38-51, wherein the oligonucleotide comprises a peptide nucleic acid.
